(19) United States
(12) Patent Application Publication
(10) Pub. No.: US 2005/0279529 A1
(43) Pub. Date: Dec. 22, 2005

(54) Wiring board, magnetic disc apparatus, and production method of wiring board

(75) Inventor: Akihiko Happoya, Tokyo (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/054,430

(22) Filed: Feb. 10, 2005

(30) Foreign Application Priority Data
Jun. 16, 2004 (JP) 2004-177879

(51) Int. Cl. H05K 1/03

(52) U.S. Cl. 174/262; 174/260; 174/255; 29/830

(57) ABSTRACT

Disclosed is a wiring board, comprising: a rigid substrate having a first surface and a second surface, wiring layers on the first surface and the second surface, and through hole's inner wall conductors electrically conducting the wiring layers on the first and the second surface, the wiring layer on the first surface including part mounting lands; a flexible substrate disposed to oppose the second surface of the rigid substrate and having connection lands on its surface which is opposite to the second surface of the rigid substrate, the connection lands being positioned to substantially agree with positions of the through hole's inner wall conductors of the rigid substrate; and a connecting member which electrically and mechanically connects the through hole's inner wall conductors and the connection lands, and a magnetic disc apparatus having the wiring board and a production method of the wiring board are disclosed.

### CROSSREFERENCE TO RELATED APPLICATIONS

This application is based upon and claims the benefit of priority from the prior Japanese Patent Application No. 2004-177879 filed on Jun. 16, 2004; the entire contents of which are incorporated herein by reference.

### BACKGROUND

1. Field of the Invention

The present invention relates to a wiring board, its production method and a magnetic disc apparatus having a wiring board, and more particularly to a wiring board suitably applied to a compact magnetic disc apparatus, a production method of the wiring board and a magnetic disc apparatus having such a wiring board.

2. Description of the Related Art

The magnetic disc apparatus, which is a typical device for storing a large amount of digital information, is demanded to be compact as portable equipment and electronic equipment have become highly functional, compact and lightweight. Such a compact magnetic disc apparatus is required to minutely contribute to miniaturization of not only a disc enclosure portion which is a container member for housing a disc or the like but also a flexible wiring board corresponding to a cable for exchanging a signal with the outside.

There may be a case where another wiring substrate for mounting electric and electronic parts is required between a mounting wiring substrate disposed within the disc enclosure and the flexible wiring substrate for connection to the outside. It is important for miniaturization that such a wiring substrate and the flexible wiring substrate are connected as easily as possible by a connecting means which does not take room.

Prior art adoptable for the above-described connection includes what is disclosed in the following patent document 1. It connects a rigid substrate and a flexible substrate by soldering through hole conductors formed in the flexible substrate and lands disposed on the rigid substrate. This structure requires the through hole conductors and the soldered joint on them for the substrate connection only, and it seems unavoidable that the structure and production process become complex.

[Patent Document 1] Japanese Patent Laid-Open Application No. 2002-232088

### SUMMARY

The present invention has been made in view of the above circumstances and provides a wiring board, its production method and a magnetic disc apparatus having the wiring board, and more particularly a wiring board in which substrates can be mutually connected with ease, its production method and a magnetic disc apparatus having such a wiring board.

According to an aspect of the present invention, there is provided a wiring board comprising a rigid substrate which has a first surface and a second surface, wiring layers at least on the first surface and the second surface, and through hole's inner wall conductors electrically conducting the wiring layer on the first surface and the wiring layer on the second surface, the wiring layer on the first surface including part mounting lands; a flexible substrate which is disposed to oppose the second surface of the rigid substrate and has connection lands on a surface which is opposite to the second surface of the rigid substrate, the connection lands being positioned to substantially agree with positions of the through hole's inner wall conductors of the rigid substrate; and a connecting member which electrically and mechanically connects the through hole's inner wall conductors of the rigid substrate and the connection lands of the flexible substrate.

Specifically, the through hole's inner wall conductors possessed by the rigid substrate are positioned to oppose the connection lands disposed on the flexible substrate of the wiring board. In this condition, the connection lands and the through hole's inner wall conductors are electrically and mechanically connected by the connecting member. Thus, the wiring layer of the rigid substrate connected to the through hole's inner wall conductors and on the opposite side of the flexible substrate can be provided with the same wiring pattern as usual. In addition, the above-described connecting member can be applied or melted in accordance with the application or melting of the solder on the wiring pattern required in the surface mounting process. Thus, the substrates can be mutually connected easily in terms of the process and structure.

According to another aspect of the present invention, there is provided a magnetic disc apparatus comprising a wiring board, which comprises a rigid substrate which has a first surface and a second surface, wiring layers at least on the first surface and the second surface, and through hole's inner wall conductors electrically conducting the wiring layer on the first surface and the wiring layer on the second surface, the wiring layer on the first surface including part mounting lands; a flexible substrate which is disposed to oppose the second surface of the rigid substrate and has connection lands on a surface which is opposite to the second surface of the rigid substrate, the connection lands being positioned to substantially agree with positions of the through hole's inner wall conductors of the rigid substrate; and a connecting member which electrically and mechanically connects the through hole's inner wall conductors of the rigid substrate and the connection lands of the flexible substrate, wherein the part mounting lands of the first surface of the rigid substrate include lands for surface mount type connector; a surface mount type connector which is mounted on the lands for surface mount type connector; and a disc enclosure having a sealed structure and being electrically connected to the wiring board via the surface mount type connector.

Specifically, this magnetic disc apparatus has a structure in that the surface mount type connector is mounted on the surface (opposite to the side where the flexible substrate is positioned) of the rigid substrate of the above-described wiring board, and the wiring board and the disc enclosure are connected via the mounted connector. Thus, the easy connection of wiring substrates is realized for the magnetic disc apparatus.

According to still another aspect of the present invention, there is provided a production method of a wiring board comprising forming through hole's inner wall conductors in prescribed positions of a rigid substrate; disposing and forming connection lands on a surface of a flexible substrate to substantially agree with positions of the formed through hole's inner wall conductors of the rigid substrate; positioning the surface of the flexible substrate, where the connection lands are disposed and formed, to oppose the rigid substrate so to substantially overlay the through hole's inner wall conductors of the rigid substrate and the connection lands of the flexible substrate; placing solder on the positions where the through hole's inner wall conductors of the rigid substrate are formed; and reflowing the placed solder.

This production method is an example of producing the above-described wiring board.

According to the present invention, a wiring board in which substrates can be mutually connected with ease, its production method and a magnetic disc apparatus having such a wiring board can be provided.

### BRIEF DESCRIPTION OF THE DRAWINGS

FIG. 1A, FIG. 1B, FIG. 1C and FIG. 1D are sectional views schematically showing a production process of the wiring substrate according to an embodiment of the present invention (first substrate).

FIG. 2A, FIG. 2B1 and FIG. 2B2 are sectional and top views schematically showing a production process of a wiring substrate according to the embodiment of the present invention (second substrate).

FIG. 3A1, FIG. 3A2, FIG. 3B, FIG. 3C and FIG. 3D are sectional and top views schematically showing a production process of a wiring board according to the embodiment of the present invention (a connection process of the first substrate and the second substrate).

FIG. 4 is a front (partly in cross section) view showing a structure of a magnetic disc apparatus according to an embodiment of the present invention.

### DETAILED DESCRIPTION

### Description of Embodiments

Embodiments of the present invention are described with reference to the drawings, which are provided for illustration only and do not limit the present invention in any respect.

As a form of an embodiment of the present invention, the above-described flexible substrate partly has a ribbon-shaped cable section, whose leading end can have a connection portion to a connector. The cable section is also provided with the connection portion to the connector.

As a form of an embodiment of a production method, the above-described process of placing solder on the positions where the through hole's inner wall conductors of the rigid substrate are formed can be made by applying cream solder. It is an example of the solder placing method. Here, the cream solder can be applied by screen printing. The solder application to plural portions can be completed effectively by the screen printing. Besides, the screen printing may be designed to apply the cream solder onto part mounting lands formed on the surface of the rigid substrate. It also applies the cream solder for mounting parts at the same time. In addition to the application by screen printing, a process of dispensing the cream solder by a dispenser can also be adopted.

As a form of an embodiment, the process of placing the solder on the positions where the through hole's inner wall conductors of the rigid substrate are formed can be made by placing solder balls. It is another example of the method of placing the solder. For example, a mounter can be used to place the solder balls. In that case, flux may be applied by, for example, previously applying the flux onto the rigid substrate by screen printing or partly immersing the surfaces of solder balls into a flux bath before placing the solder balls on the rigid substrate. Besides, the process of placing the solder on the positions where the through hole's inner wall conductors are formed can be made by applying the cream solder and placing the solder balls as a form of an embodiment. For example, it can be adopted if an amount of solder becomes insufficient when the screen printing only is employed.

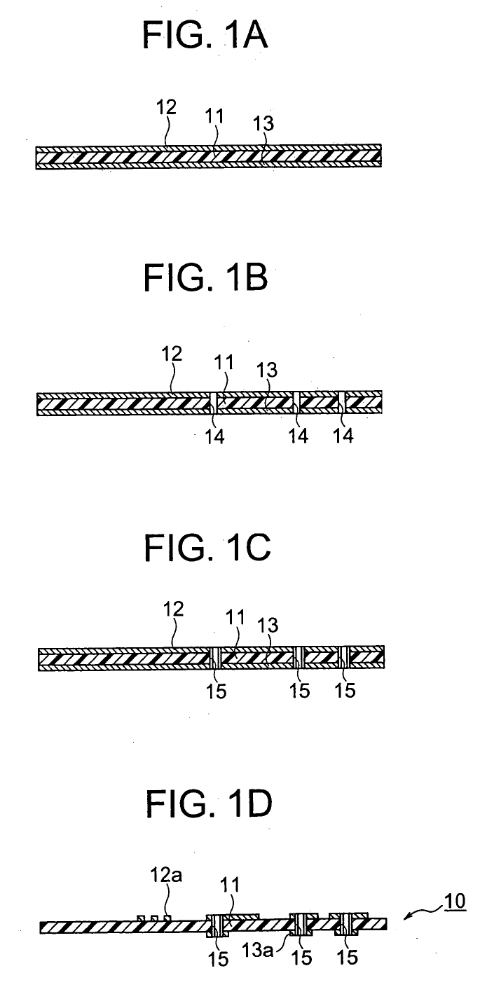

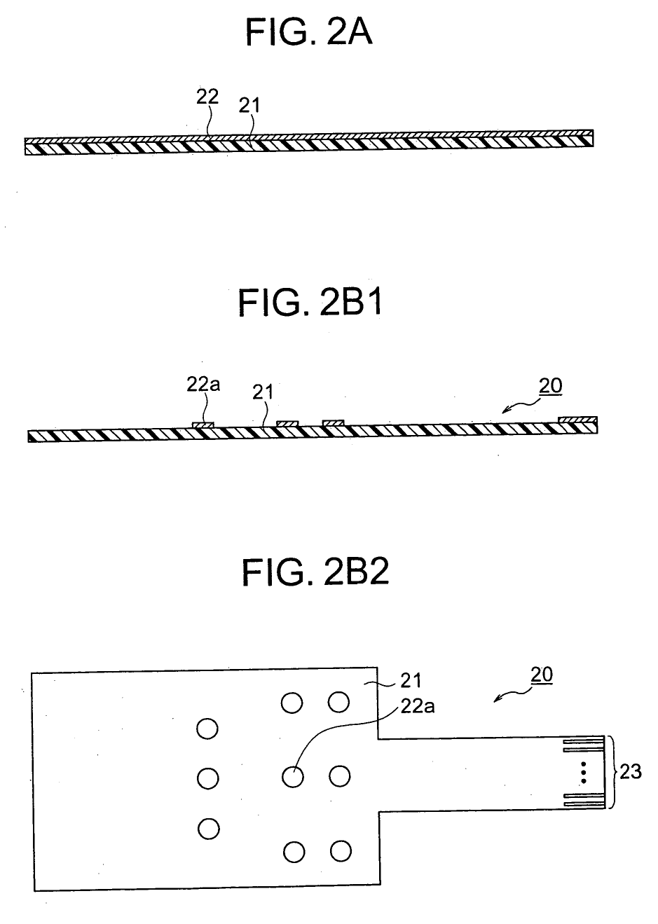

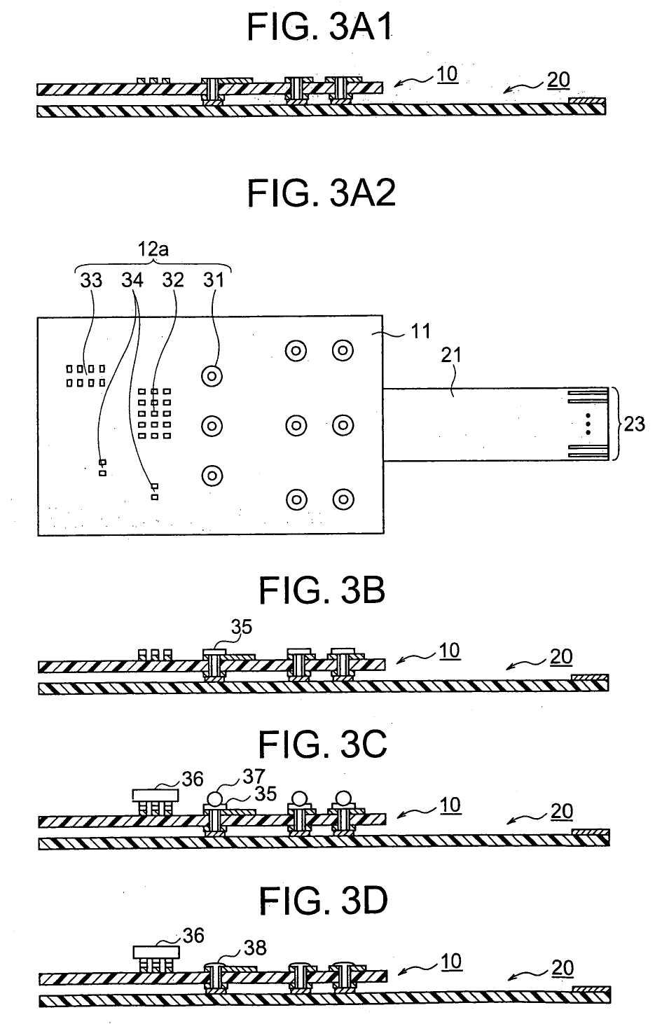

Based on the foregoing, embodiments of the present invention will be described below with reference to the drawings. FIG. 1A to FIG. 3D are sectional views (including top views) schematically showing a production process of a wiring board according to one embodiment of the present invention. FIG. 1A to FIG. 1D show a production process of a first substrate, FIG. 2A to FIG. 2B2 show a production process of a second substrate, and FIG. 3A1 to FIG. 3D show a connection process of the first substrate and the second substrate. In the drawings, the same reference numerals are allotted to the same or corresponding elements.

First, description will be made with reference to FIG. 1A to FIG. 1D. A double-sided copper-plated insulation plate, which has metal (copper) layers 12, 13 disposed on both sides and has an insulation plate 11 formed of a rigid material (e.g., epoxy resin), is prepared as shown in FIG. 1A. The insulation plate 11 has a thickness of, for example, 0.2 mm. Then, through holes 14 are formed in prescribed positions of the double-sided copper-plated insulation plate by, for example, drilling as shown in FIG. 1B. Then, conductors (through hole's inner wall conductors) 15 are formed on the inside walls of the formed through holes 14 as shown in FIG. 1C. The conductors 15 can be formed by, for example, a two-stage plating process of electroless plating and electrolysis plating. The copper layers 12, 13 become the conductors for supplying electricity in the electrolysis plating process.

Then, the copper layers 12, 13 on both sides of the insulation plate 11 are patterned into a prescribed pattern so to have patterned copper layers 12a, 13a as shown in FIG. 1D. For example, this patterning can be made by etching by a known photolithography method. The patterned copper layers 12a, 13a have portions connected to the through hole's inner wall conductors 15, and the patterned copper layer 12a on one side has lands for mounting parts as shown in the drawing. Besides, the copper layers 12a, 13a include a wiring pattern to electrically conduct to the individual lands. After the step of FIG. 1D, a solder resist (not shown) may be formed on the wiring pattern which is not required for soldered connection, and a plated layer (not shown) for preventing corrosion may be formed on the exposed patterned copper layer 12a. Thus, a first substrate 10 is provided.

The substrate 10 is configured as a so-called through hole double-sided substrate but may be a multilayer substrate having a wiring layer thereinside if it has the through hole's inner wall conductors 15 capable of electrically conducting the copper layers 12a, 13a on both sides. The substrate 10 has a size of, for example, 24 mm×32 mm because it is used as a board attached to a compact magnetic disc apparatus.

Then, a production process of a second substrate 20 will be described with reference to FIG. 2A to FIG. 2B2. First, an insulation plate 21 formed of a flexible material (e.g., polyimide resin) having a metal (copper) layer 22 on its one side is provided as shown in FIG. 2A. The insulation plate 21 has a thickness of, for example, 0.2 mm. Then, the copper layer 22 is patterned into a prescribed pattern to form a patterned copper layer 22a as shown in FIG. 2B1. This patterning can also be made by etching by, for example, the known photolithography method.

As shown in FIG. 2B2 (=top view), the patterned copper layer 22a includes as the connection lands for connection with the first substrate 10 at least a pattern which agrees with the located positions of the through hole's inner wall conductors 15 formed in the first substrate 10. In this case, it also includes a pattern as electrodes of a connector connecting portion 23 for connection with the outside. It is not shown but the electrodes of the connector connecting portion 23 and the individual connection lands are electrically conducted by the wiring pattern which is a part of the patterned copper layer 22a.

After the process shown in FIG. 2B1 and FIG. 2B2, a cover lay (not shown) may be formed on the wiring pattern which is not required for soldered connection, and a plated layer (not shown) for preventing corrosion may be formed on the pattern of the exposed copper layer 22a. Thus, the second substrate 20 is provided.

The substrate 20 is configured as a so-called one-sided substrate but may be a double-sided substrate or a multilayered substrate. It can be made to have the same size as that of the first substrate 10 except the ribbon-shape protruded portion. The ribbon-shape protruded portion functions as a flexible cable portion. Therefore, its leading end is provided with the connector connecting portion 23.

Then, a process of connecting the first substrate 10 and the second substrate 20 will be described with reference to FIG. 3A1 to FIG. 3D. In the connecting process, the surface of the second substrate 20 where the patterned copper layer 22a is disposed and formed is positioned to face the surface opposite to the surface of the first substrate 10 where the part mounting lands are disposed and formed as shown in FIG. 3A1 and FIG. 3A2, and they are overlaid such that the through hole's inner wall conductors 15 and the copper layer 22a as the connection lands of the substrate 20 are overlaid. As shown in FIG. 3A2, the patterned copper layer 12a on the top surface of the first substrate 10 include lands such as through hole coupling lands 31, lands 32 for surface mount type connector, lands 33 for electronic parts, and lands 34 for electric parts. It is not shown but necessary electrical conduction is made between the lands by the wiring pattern which is a part of the copper layer 12a.

Then, cream solder 35 is applied to prescribed regions on the overlaid copper layer 12a of the first substrate 10 as shown in FIG. 3B. The cream solder 35 can be applied efficiently by, for example, screen printing. The screen printing itself is well known and, therefore, its details are not described here. Briefly, it is a technology of transfering a composition in paste or liquid such as cream solder through a screen mask having a mesh (net) or pits (through hole) formed into a prescribed pattern. The cream solder 35 is applied to cover the tops of the through hole's inner wall conductors 15 and also onto the individual lands for mounting parts as shown in the drawing. A dispenser can also be used instead of the screen printing to dispense the cream solder 35 onto the copper layer 12a.

Then, by for example a mounter, as shown in FIG. 3C, solder balls 37 are placed on the through hole's inner wall conductors 15 where the cream solder 35 is applied, and a surface-mounted component (surface mount type connector 36 in the drawing) is placed on the individual lands where the cream solder 35 is applied. The solder balls 37 supplement a shortage of volume when the cream solder 35 melts and is taken into the spaces of the through hole's inner wall conductors 15. They are not required when the first substrate 10 is sufficiently thin or the cream solder 35 on the tops of the through hole's inner wall conductors 15 can be applied in a satisfactorily large volume.

Then, the entire board is placed in, for example, a reflow furnace to reflow the cream solder 35 and the solder balls 37 as shown in FIG. 3D. Thus, inside the through hole's inner wall conductors 15 of the first substrate 10 there are filled with solder 38, and the solder 38 reaches the connection lands of the copper layer 22a on the second substrate 20 to electrically and mechanically connect the first substrate 10 and the second substrate 20. A component such as the surface mount type connector 36 is also mounted on the substrate 10 by soldering.

The wiring board with the above-described structure having the substrates mutually connected can connect the second substrate 20 at the same time by using both the structure of the lands and the like for mounting parts on the first substrate 10 and the process of mounting the parts on the lands. Thus, the substrates can be mutually connected easily in terms of the structure and process.

In the process shown in FIG. 3B, the cream solder 35 is applied onto the through hole's inner wall conductors 15, but it is also possible to employ a production method by that the solder balls 37 are placed on the through hole's inner wall conductors 15 only with the cream solder 35 applied onto the other lands only. For the application of the flux onto the through hole's inner wall conductors 15 in this case, it is possible that, for example, the flux is previously screen printed on the first substrate 10, the solder balls 37 have the surfaces partly immersed in the flux bath by the mounter and are placed on the first substrate 10, or the like. In this production method, the connection of the first substrate 10 and the second substrate 20 is realized simultaneously by using the structure of the lands for mounting parts on the first substrate 10 and the process of mounting the parts on the lands.

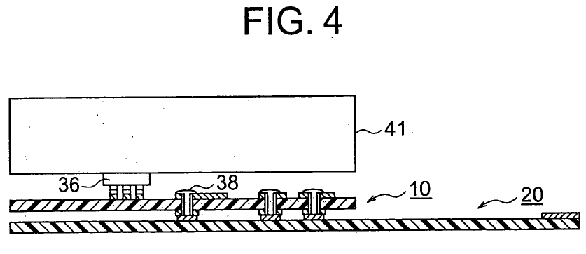

Then, an embodiment of attaching the wiring board produced as described above to a magnetic disc apparatus will be described with reference to FIG. 4. FIG. 4 is a front (partly in cross section) view showing a structure of the magnetic disc apparatus according to an embodiment of the present invention. The same reference numerals are allotted to the same or corresponding elements as those described above, and their description is omitted unless there is any additional matter.

As shown in FIG. 4, this magnetic disc apparatus has the surface mount type connector 36 mounted on the first substrate 10 of the above-described board which has the first substrate 10 and the second substrate 20 connected and a disc enclosure 41 which has a sealed structure and is electrically connected with the above-described board via the surface mount type connector 36. The disc enclosure 41 has therein a mounting board which is electrically connected to the surface mount type connector 36. This magnetic disc apparatus has realized the easy connection of the wiring substrates for the magnetic disc apparatus. Between them, parts are mounted on the rigid first substrate 10, and the ribbon-shaped projection of the flexible second substrate 20 functions as a cable. Thus, various functions required for the board are realized by a compact and easy structure.

It is to be understood that the present invention is not limited to the specific embodiments thereof illustrated herein, but it is understood that all changes that come within the range of the following claims are included in the present invention.

1. A wiring board, comprising:
a rigid substrate which has a first surface and a second surface, wiring layers on the first surface and the second surface, and through hole's inner wall conductors electrically conducting the wiring layer on the first surface and the wiring layer on the second surface, the wiring layer on the first surface including part mounting lands;
a flexible substrate which is disposed to oppose the second surface of the rigid substrate and has connection lands on a surface which is opposite to the second surface of the rigid substrate, the connection lands being positioned to substantially agree with positions of the through hole's inner wall conductors of the rigid substrate; and
a connecting member which electrically and mechanically connects the through hole's inner wall conductors of the rigid substrate and the connection lands of the flexible substrate.

2. A wiring board according to claim 1, wherein the flexible substrate partly has a ribbon-shaped cable portion, whose leading end has a connection portion to a connector.

3. A magnetic disc apparatus, comprising:
a wiring board, which comprises a rigid substrate which has a first surface and a second surface, wiring layers on the first surface and the second surface, and through hole's inner wall conductors electrically conducting the wiring layer on the first surface and the wiring layer on the second surface, the wiring layer on the first surface including part mounting lands; a flexible substrate which is disposed to oppose the second surface of the rigid substrate and has connection lands on a surface which is opposite to the second surface of the rigid substrate, the connection lands being positioned to substantially agree with positions of the through hole's inner wall conductors of the rigid substrate; and a connecting member which electrically and mechanically connects the through hole's inner wall conductors of the rigid substrate and the connection lands of the flexible substrate, wherein the part mounting lands of the first surface of the rigid substrate include lands for surface mount type connector;
a surface mount type connector which is mounted on the lands for surface mount type connector; and
a disc enclosure having a sealed structure and being electrically connected to the wiring board via the surface mount type connector.

4. A production method of a wiring board, comprising:
forming through hole's inner wall conductors in prescribed positions of a rigid substrate;
disposing and forming connection lands on a surface of a flexible substrate to substantially agree with positions of the formed through hole's inner wall conductors of the rigid substrate;
positioning the surface of the flexible substrate, where the connection lands are disposed and formed, to oppose the rigid substrate so to substantially overlay the through hole's inner wall conductors of the rigid substrate and the connection lands of the flexible substrate;
placing solder on the positions where the through hole's inner wall conductors of the rigid substrate are formed; and
reflowing the placed solder.

5. A production method of a wiring board according to claim 4, wherein the placing of the solder on the positions where the through hole's inner wall conductors of the rigid substrate are formed is performed by applying cream solder.

6. A production method of a wiring board according to claim 4, wherein the placing of the solder on the positions where the through hole's inner wall conductors of the rigid substrate are disposed is performed by placing solder balls.

7. A production method of a wiring board according to claim 4, wherein the placing of the solder on the positions where the through hole's inner wall conductors of the rigid substrate are disposed is performed by applying cream solder and placing solder balls.

8. A production method of a wiring board according to claim 5, wherein the cream solder is applied by screen printing.

9. A production method of a wiring board according to claim 8, wherein the screen printing also applies the cream solder onto part mounting lands formed on the surface of the rigid substrate.
